(19) United States
(12) Patent Application Publication
(10) Pub. No.: US 2023/0238419 A1
(43) Pub. Date: Jul. 27, 2023

(54) ULTRAVIOLET LIGHT-EMITTING DEVICE

(71) Applicant: Photon Wave Co., Ltd., Gyeonggi-do (KR)

(72) Inventors: Youn Joon SUNG, Gyeonggi-do (KR); Hae Jin PARK, Seoul (KR); Seung Kyu OH, Gyeonggi-do (KR); Jae Bong SO, Gyeonggi-do (KR); Gil Jun LEE, Gyeonggi-do (KR); Il Gyun CHOI, Gyeonggi-do (KR)

(73) Assignee: Photon Wave Co., Ltd., Gyeonggi-do (KR)

(21) Appl. No.: 17/792,421

(22) PCT Filed: Sep. 24, 2021
(86) PCT No.: PCT/KR2021/013039

§ 371 Date: Jul. 13, 2022

(30) Foreign Application Priority Data
Jan. 21, 2021 (KR) 10-2021-0008657
Aug. 27, 2021 (KR) 10-2021-0113918
Aug. 27, 2021 (KR) 10-2021-0113919

(51) Int. Cl. H01L 27/15

(52) U.S. Cl. CPC H01L 27/153

(57) ABSTRACT

An embodiment discloses an ultraviolet light-emitting device including: a light-emitting structure including a plurality of light-emitting portions disposed on a first conductive type semiconductor layer, the plurality of light-emitting portions including an active layer and a second conductive type semiconductor layer; a first contact electrode disposed on the first conductive type semiconductor layer; a second contact electrode disposed on the second conductive type semiconductor layer; a first cover electrode disposed on the first contact electrode; and a second cover electrode disposed on the second contact electrode, wherein the light-emitting structure includes an intermediate layer formed in an etched region through which the first conductive type semiconductor layer is exposed, the intermediate layer including a lower composition of aluminum than the first conductive type semiconductor layer, wherein the intermediate layer includes a first intermediate region disposed between the plurality of light-emitting portions, and a second intermediate region surrounding edges of the first conductive type semiconductor layer and connected to opposite ends of the plurality of first intermediate regions, wherein the first contact electrode includes a first sub-electrode disposed on the first intermediate region, and a second sub-electrode disposed on the second intermediate region.

### TECHNICAL FIELD

An embodiment relates to an ultraviolet light-emitting device.

### BACKGROUND ART

As a kind of important solid element that converts electrical energy into light, a light-emitting diode (LED) generally includes an active layer of semiconductor material interposed between two opposing doped layers. When a bias voltage is applied to the opposite ends of the two doped layers, holes and electrons are injected into the active layer and then recombined therein to generate light. The light generated in an active region is emitted in all directions, and escapes out of a semiconductor chip through all exposed surfaces. The LED packaging is generally used to direct the escaping light in the form of desired output emission.

With a rapid demand for products subjected to water treatment, sterilization, interest in an ultraviolet light-emitting device has been increasing. As demand for a high-power ultraviolet light-emitting device increases, many kinds of research and developments have been made to improve optical power.

However, the ultraviolet light-emitting device has a problem in that a light-emitting efficiency is low because its light extraction efficiency and current spreading effect are lower than those of a visible light-emitting device.

### DISCLOSURE

### Technical Problem

An embodiment is to provide an ultraviolet light-emitting device with an improved light-emitting efficiency.

Problems to be solved in the embodiment are not limited thereto, but may include objects or effects that can be grasped from the following solution or the following mode for carrying out the embodiment.

### Technical Solution

According to an embodiment of the disclosure, an ultraviolet light-emitting device includes: a light-emitting structure including a plurality of light-emitting portions disposed on a first conductive type semiconductor layer, the plurality of light-emitting portions including an active layer and a second conductive type semiconductor layer; a first contact electrode disposed on the first conductive type semiconductor layer; a second contact electrode disposed on the second conductive type semiconductor layer; a first cover electrode disposed on the first contact electrode; and a second cover electrode disposed on the second contact electrode, wherein the light-emitting structure includes an intermediate layer formed in an etched region through which the first conductive type semiconductor layer is exposed, the intermediate layer including a lower composition of aluminum than the first conductive type semiconductor layer, wherein the intermediate layer includes a first intermediate region disposed between the plurality of light-emitting portions, and a second intermediate region surrounding edges of the first conductive type semiconductor layer and connected to opposite ends of the plurality of first intermediate regions, wherein the first contact electrode includes a first sub-electrode disposed on the first intermediate region, and a second sub-electrode disposed on the second intermediate region.

The second contact electrode may include a material different from that of the first contact electrode.

The second contact electrode may include gold (Au) or rhodium (Rh).

The ultraviolet light-emitting device may further include a first insulating layer formed on the etched region and including a first through-hole through which the intermediate layer is exposed, wherein a first spacing region is formed between the intermediate layer and the first through-hole.

The first contact electrode may cover an upper portion of the first insulating layer, and the first contact electrode may be formed in the first spacing region and be in contact with the first conductive type semiconductor layer.

The first insulating layer may include a second through-hole through which the second conductive type semiconductor layer is partially exposed, the second contact electrode may be disposed on the second conductive type semiconductor layer exposed through the second through-hole, and a second spacing region may be formed being spaced apart from the second through-hole.

The second cover electrode may be extended to the second spacing region and be in contact with the second conductive type semiconductor layer.

The second spacing region where the second conductive type semiconductor layer is exposed through the second through-hole may have higher reflectivity than a region disposed in the first cover electrode.

The total area of the first contact electrode may be larger than the total area of the first cover electrode, and the total area of the second contact electrode may be smaller than the total area of the second cover electrode.

The total area of the intermediate layer may be larger than the area of the first cover electrode.

The first contact electrode may include a plurality of split electrodes spaced apart

The first cover electrode may be disposed on the plurality of split electrodes.

The spaces between the plurality of split electrodes may be different.

### Advantageous Effects

According to an embodiment, an ultraviolet light-emitting device may be improved in a light-emitting efficiency and light extraction efficiency.

Various and beneficial advantages and effects of the disclosure are not limited to the foregoing description, but may be more easily understood in the middle of describing specific embodiments of the disclosure.

### DESCRIPTION OF DRAWINGS

FIG. 1 is a plan view of a light-emitting device according to an embodiment of the disclosure.

FIG. 2A is a cross-sectional view, taken along line A-A′ in FIG. 1.

FIG. 2B is a cross-sectional view, taken along line B-B′ in FIG. 1.

FIG. 3 is a partially enlarged view of ‘A’ in FIG. 2A.

FIG. 4 is a plan view showing an intermediate layer surrounding a plurality of light-emitting portions.

FIG. 5 is a plan view showing a first contact electrode surrounding a plurality of light-emitting portions.

FIG. 6 is a plan view showing a light-emitting device according to another embodiment of the disclosure.

FIG. 7 is a plan view showing an intermediate layer, a first contact electrode, and a first cover electrode.

FIG. 8 is a plan view showing an intermediate layer with a second splitting region.

FIG. 9 is a plan view showing a first contact electrode with a first splitting region.

FIG. 10 is a plan view showing a first cover electrode.

FIG. 11 is a cross-sectional view taken along line C-C′ in FIG. 7.

FIG. 12 is a cross-sectional view taken along line D-D′ in FIG. 7.

FIG. 13 is a cross-sectional view taken along line E-E′ in FIG. 7.

FIG. 14 shows an alternative example to FIG. 13.

FIG. 15 is a graph showing optical power measured in a comparative example where a splitting region is absent from a first contact electrode and an embodiment where a splitting region is present in a first contact electrode.

FIG. 16 is a graph showing operating voltage measured in a comparative example where a splitting region is absent from a first contact electrode and an embodiment where a splitting region is present in a first contact electrode.

FIG. 17A is a plan view of a light-emitting device according to another embodiment of the disclosure.

FIG. 17B is a cross-sectional view, taken along line F-F′ in FIG. 17A.

FIG. 18 is a first alternative example to FIG. 9.

FIG. 19 is a second alternative example to FIG. 9.

FIG. 20 is a third alternative example to FIG. 9.

FIG. 21 is a fourth alternative example to FIG. 9.

FIG. 22 is a fifth alternative example to FIG. 9.

### MODE FOR INVENTION

Embodiments set forth herein may be modified in other forms, or various embodiments may be combined with each other, and thus the scope of the disclosure is not limited to each of the embodiments described below.

Although matters described in a specific embodiment is not described in other embodiments, the matters may be understood as related to the other embodiments unless there are no conflicting or contradictory description to the matters in the other embodiments.

For example, when the feature of a configuration A are described in a specific embodiment and the features of a configuration B are described in another embodiment, it will be understood that the combined features of the configurations A and B fall within the scope of the disclosure as long as there are no conflicting or contradictory description to the combined features even though the combined features are not explicitly described in any embodiment.

In terms of describing an embodiment, when an element is formed “on (above) or below (under)” another element, the terms “on (above) or below (under)” include the meaning of the two elements being in direct contact with each other and the meaning of the two elements with one or more other elements disposed therebetween. Further, the terms “on (above) or below (under)” may include the meaning of not only an upward direction but also a downward direction with respect to one element.

Below, embodiments of the disclosure will be described in detail with reference to the accompanying drawings so as to be easily implemented by a person having ordinary knowledge in the art to which the disclosure pertains

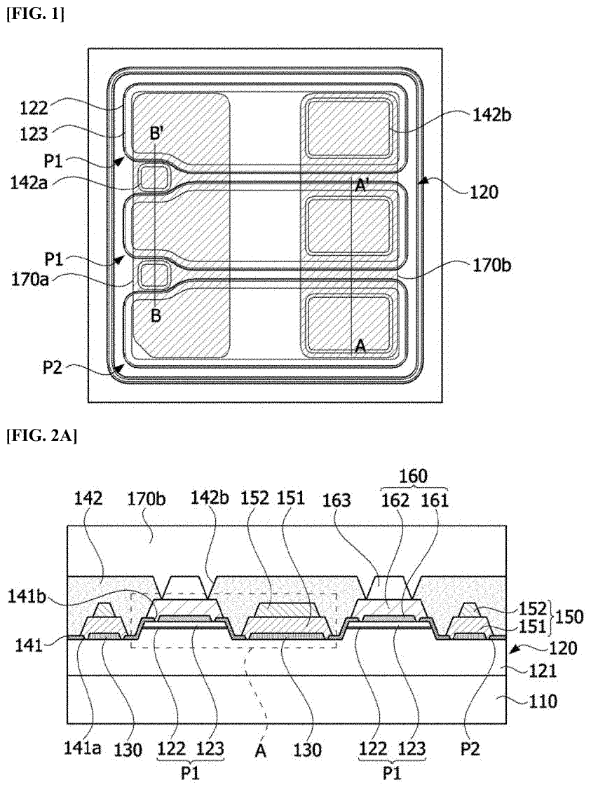

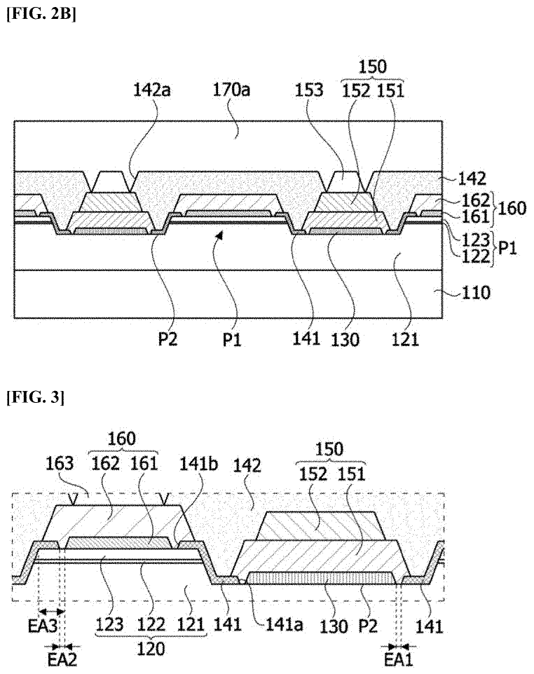

FIG. 1 is a plan view of a light-emitting device according to an embodiment of the disclosure. FIG. 2A is a cross-sectional view, taken along line A-A′ in FIG. 1. FIG. 2B is a cross-sectional view, taken alone line B-B′ in FIG. 1.

Referring to FIGS. 1, 2A, and 2B, a light-emitting structure 120 according to an embodiment of the disclosure may output light of an ultraviolet wavelength band. For example, the light-emitting structure 120 may output light UV-A in a near-ultraviolet wavelength band, light UV-B in a far-ultraviolet wavelength band, or light UV-C in a deep-ultraviolet wavelength band.

For example, the light UV-A in the near-ultraviolet wavelength band may have a peak wavelength in a range of 320 nm to 420 nm, the light UV-B in the far-ultraviolet wavelength band may have a peak wavelength in a range of 280 nm to 320 nm, and the light UV-C in the deep-ultraviolet wavelength band may have a peak wavelength in a range of 100 nm to 280 nm.

When the light-emitting structure 120 emits light in the ultraviolet wavelength band, each semiconductor layer of the light-emitting structure 120 may include a material of Inx₁Al_{y1}Ga_{1-x1-y1}N (0≤x1≤1, 0≤y1≤1, 0≤x1+y1≤1) containing aluminum (Al). Here, the composition of Al may be represented as a ratio of the atomic weight of Al to the total atomic weight including the atomic weight of In, the atomic weight of Ga, and the atomic weight of Al. For example, when the composition of Al is 40%, the composition of Ga is 60% and the material of each semiconductor layer is represented as Al_{0.4}Ga_{0.6}N.

Further, in terms of the description in the embodiment, the meaning of low or high composition may be understood as a difference in percent between the compositions of the semiconductor layer. For example, when the first semiconductor layer contains aluminum of 30% and the second semiconductor layer contains aluminum of 60%, it may be understood that the composition of aluminum in the second semiconductor layer is higher by 30% than that in the first semiconductor layer.

A substrate 110 may contain a material selected among sapphire (Al₂O₃), SiC, GaAs, GaN, ZnO, Si, GaP, InP and Ge, but is not limited thereto. The substrate 110 may be a transparent substrate through which light in an ultraviolet wavelength band is allowed to pass.

A buffer layer (not shown) may buffer a lattice mismatch between the substrate 110 and the semiconductor layers. The buffer layer may be formed by a combination of group III elements and group V elements, or may include one among AlN, AlGaN, InAlGaN, and AlInN. The buffer layer may contain AlN, but is not limited thereto. The buffer layer may contain a dopant, but is not limited thereto.

A first conductive type semiconductor layer 121 may be embodied by a semiconductor formed by group III-V compounds, group II-VI compounds, etc., and may be doped with a first dopant. The first conductive type semiconductor layer 121 may be selected from semiconductor materials having an empirical formula of Inₓ₁Al_{y1}Ga_{1-x1-y1}N (0≤x1≤1, 0≤y1≤1, 0≤x1+y1≤1), for example, AlGaN, AlN, InAlGaN, and the like. In addition, the first dopant may include Si, Ge, Sn, Se, Te, and the like n-type dopant. When the first dopant is the n-type dopant, the first conductive type semiconductor layer 121 doped with the first dopant may be an n-type semiconductor layer.

An active layer 122 may be sandwiched between the first conductive type semiconductor layer 121 and a second conductive type semiconductor layer 123. The active layer 122 is a layer where electrons (or holes) injected from the first conductive type semiconductor layer 121 and holes (or electrons) injected from the second conductive type semiconductor layer 123 meet. In the active layer 122, the electrons recombine with the holes and transition to a lower energy level while emitting light having an ultraviolet wavelength.

The active layer 122 may have any one of a single well structure, a multi-well structure, a single quantum well structure, a multi-quantum well (MQW) structure, a quantum dot structure, and a quantum wire structure, but is not limited thereto.

The active layer 122 may include a plurality of well layers and barrier layers. The well layer and the barrier layer may have an empirical formula of Inₓ₂Al_{y2}Ga_{1-x2-y2}N (0≤x2≤1, 0≤y2≤1, 0≤x2+y2≤1). The composition of Al in the well layer may be varied depending on the wavelengths of light to be emitted. The higher the composition of Al, the shorter the wavelength of light emitted from the well layer.

The second conductive type semiconductor layer 123 is formed on the active layer 122, may be embodied by a semiconductor formed by group III-V compounds, group II-VI compounds, etc., and may be doped with a second dopant.

The second conductive type semiconductor layer 123 may contain a semiconductor material having an empirical formula of Inₓ₅Al_{y2}Ga_{1-x5-y2}N (0≤x5≤1, 0≤y2≤1, 0≤x5+y2≤1), or a material selected among AlInN, AlGaAs, GaP, GaAs, GaAsP, and AlGaInP.

When the second dopant includes Mg, Zn, Ca, Sr, Ba and the like p-type dopant, the second conductive type semiconductor layer 123 doped with the second dopant may be a p-type semiconductor layer.

An electron-blocking layer (EBL) may be disposed between the active layer 122 and the second conductive type semiconductor layer 123. The EBL (not shown) serves as a constraining layer for the active layer 122 to reduce electron leakage.

In the light-emitting structure 120, the active layer 122 and the second conductive type semiconductor layer 123 are partially removed by mesa etching, thereby forming an etched region P2 through which the first conductive type semiconductor layer 121 is exposed, and a light-emitting portion P1 in which the and the active layer 122 and the second conductive type semiconductor layer 123 remain.

The ultraviolet light-emitting device has a relatively higher emission probability in a transverse magnetic (TM) mode for lateral emission than a light-emitting device that emits blue light, and it may be advantageous to enlarge the lateral surface of the active layer 122 as large as possible. Therefore, the light-emitting portion P1 is split into a plurality of pieces to increase the exposed area of the active layer 122, thereby improving the extraction efficiency of the light emitted through the lateral surface. The embodiment discloses three light-emitting portions P1, but there are no specific limits to the number of light-emitting portions P1.

The light-emitting structure 120 may include an intermediate layer 130 selectively regrown on the first conductive type semiconductor layer 121. The first conductive type semiconductor layer 121 may be exposed in a remaining area except for a region where the plurality of light-emitting portions P1 is formed.

The intermediate layer 130 may be a selectively regrown n-type semiconductor layer. The material of the intermediate layer 130 may be the same as that of the first conductive type semiconductor layer 121. For example, the first conductive type semiconductor layer 121 and the intermediate layer 130 may have compositions of AlGaN.

However, the composition of Al in the intermediate layer 130 may be lower than that in the first conductive type semiconductor layer 121. For example, the composition of Al in the intermediate layer 130 may range from 0% to 30%. In other words, the intermediate layer 130 may contain GaN or AlGaN. With this composition, a first contact electrode 151 and the intermediate layer 130 are decreased in ohmic resistance, and therefore their operating voltages are lowered.

The intermediate layer 130 may be doped with the first dopant (Si) at a concentration of 1E17/cm³ to 1E20/cm³. The concentration of the first dopant (Si) in the intermediate layer 130 may be higher than that in the first conductive type semiconductor layer 121, but not limited thereto. Alternatively, the concentration of the first dopant (Si) in the intermediate layer 130 may be equal to or lower than that in the first conductive type semiconductor layer 121.

The intermediate layer 130 may have a superlattice structure in which a first intermediate layer (not shown) and a second intermediate layer (not shown) different in the composition of Al are stacked a plurality of times. The composition of Al in the first intermediate layer may be higher than that in the second intermediate layer. Each of the first intermediate layer and the second intermediate layer may have a thickness of 5 nm to 10 nm, but is not limited thereto.

The first intermediate layer may satisfy an empirical formula of AlₓGa₁₋ₓN (0.6≤x≤1), and the second intermediate lay may satisfy an empirical formula of _{AlyGa1-y}N (0≤y≤0.5). For example, the first intermediate layer may contain AlGaN, and the second intermediate layer may contain GaN, but is not limited thereto. Alternatively, both the first intermediate layer and the second intermediate layer may contain AlGaN. Even in this case, the composition of Al in the first intermediate layer may be higher than that in the second intermediate layer.

With this superlattice structure, stress caused by a lattice mismatch is decreased while minimizing absorption of ultraviolet light, thereby improving the stability of the device.

A first insulating layer 141 may be disposed on partial regions of the etched region P2, the lateral surface of the light-emitting portion P1, and the top surface of the light-emitting portion P1. The first insulating layer 141 may include a first through-hole 141a through which the first conductive type semiconductor layer 121 is exposed in the etched region P2. In other words, the first insulating layer 141 may adjust the area for regrowing the intermediate layer 130 by partially exposing the etched region P2. The first insulating layer 141 may contain at least one selected from a group consisting of SiO₂, SiₓO_{y}, Si₃N₄, SiₓN_{y}, SiOₓN_{y}, Al₂O₃, TiO₂, and AlN.

When the area for the regrowth is large, the intermediate layer may regrow relatively quickly but have a rough surface. On the other hand, when the area for the regrowth is small, the intermediate layer may regrow relatively slowly but have a smooth surface. Therefore, according to an embodiment, the area of the first through-hole is adjusted, thereby forming a regrowth layer having a low roughness while its regrowth is completed in a relatively short time.

The first contact electrode 151 may be disposed on the intermediate layer 130. The first contact electrode 151 may contain at least one among aluminum (Al), chrome (Cr), palladium (Pd), rhodium (Rh), platinum (Pt), titanium (Ti), nickel (Ni), gold (Au), indium (In), tin (Sn), tungsten (W), and copper (Cu).

For example, the first contact electrode 151 may include a first layer that contains at least one of Cr, Ti, and TiN, and a second layer that contains at least one of Al, Rh, and Pt. However, without limitations, the first contact electrode 151 may include various structures and materials to effectively block ultraviolet light emitted to the etched region P2. For example, the first contact electrode 151 may include layers of Cr/Al/Ni/Au/Ni/Ti.

The first contact electrode 151 may be extended to an upper portion of the first insulating layer 141. With this structure, the reflective area of the first contact electrode 151 is enlarged, thereby improving the light extraction efficiency. Therefore, the whole region of the intermediate layer 130 may overlap the first contact electrode 151 in a vertical direction, and the area of the first contact electrode 151 may be larger than the area of the intermediate layer 130.

A first cover electrode 152 may be disposed on the first contact electrode 151. The first cover electrode 152 may contain at least one among aluminum (Al), chrome (Cr), palladium (Pd), rhodium (Rh), platinum (Pt), titanium (Ti), nickel (Ni), gold (Au), indium (In), tin (Sn), tungsten (W) and copper (Cu). The material of the first cover electrode 152 may differ from that of the first contact electrode 151. For example, the first cover electrode 152 may include Ti/Au/Ni/Ti layers. However, without limitations, the material of the first cover electrode 152 may be the same as that of the first contact electrode 151.

A second contact electrode 161 may be disposed on the light-emitting portion P1. Specifically, the second contact electrode 161 may be disposed on the second conductive type semiconductor layer 123 exposed through a second through-hole 141b of the first insulating layer 141.

The second contact electrode 161 may contain at least one among aluminum (Al), chrome (Cr), palladium (Pd), rhodium (Rh), platinum (Pt), titanium (Ti), nickel (Ni), gold (Au), indium (In), tin (Sn), tungsten (W) and copper (Cu).

For example, the second contact electrode 161 may include layers of Ni/Au or Ni/Rh. With this structure, the second contact electrode 161 is improved in ohmic properties and adhesive strength, and has a characteristic of partially reflecting ultraviolet light. However, without limitations, the second contact electrode 161 may have various structures and materials to effectively block the ultraviolet light emitted from the active layer 122.

A second cover electrode 162 may be disposed on the second contact electrode 161. The second cover electrode 162 may contain at least one among aluminum (Al), chrome (Cr), palladium (Pd), rhodium (Rh), platinum (Pt), titanium (Ti), nickel (Ni), gold (Au), indium (In), tin (Sn), tungsten (W) and copper (Cu). The material of the second cover electrode 162 may be different from that of the second contact electrode 161. However, without limitations, the material of the second cover electrode 162 may be the same as that of the second contact electrode 161.

The second cover electrode 162 may include Ti/Au/Ni/Ti layers. The material of the second cover electrode 162 may be the same as that of the first cover electrode 152.

A second insulating layer 142 completely covers the first cover electrode 152 and the second cover electrode 162, and includes a third through-hole 142a through which the first cover electrode 152 is exposed, and a fourth through-hole 142b through which the second cover electrode 162 is exposed. The fourth through-hole 142b is larger than the third through-hole 142a, thereby improving a hole injection efficiency.

The material of the second insulating layer 142 may be different from that of the first insulating layer 141. For example, the second insulating layer 142 may be an inter-metal dielectric (IMD). However, without limitations, the material of the first insulating layer 141 may be the same as that of the second insulating layer 142. The second insulating layer 142 may contain at least one selected from a group consisting of SiO₂, SiₓO_{y}, Si₃N₄, SiₓN_{y}, SiOₓN_{y}, Al₂O₃, TiO₂, and AlN. The first insulating layer 141 and the second insulating layer 142 may function as a single insulating layer.

A second upper electrode 163 may be disposed on the second cover electrode 162. A second pad 170b may be electrically connected to the second conductive type semiconductor layer 123 by the second upper electrode 163, the second cover electrode 162, and the second contact electrode 161.

A first upper electrode 153 may be disposed on the first cover electrode 152. A first pad 170a may be electrically connected to the first conductive type semiconductor layer 121 by the first upper electrode 153, the first cover electrode 152, and the first contact electrode 151. The first upper electrode 153 and the second upper electrode 163 are disposed on the cover electrodes and serve to be on a level with the surrounding regions, thereby relieving stress during bonding. The first upper electrode 153 and the second upper electrode 163 may contain Ti/Ni/Au, but are not limited thereto.

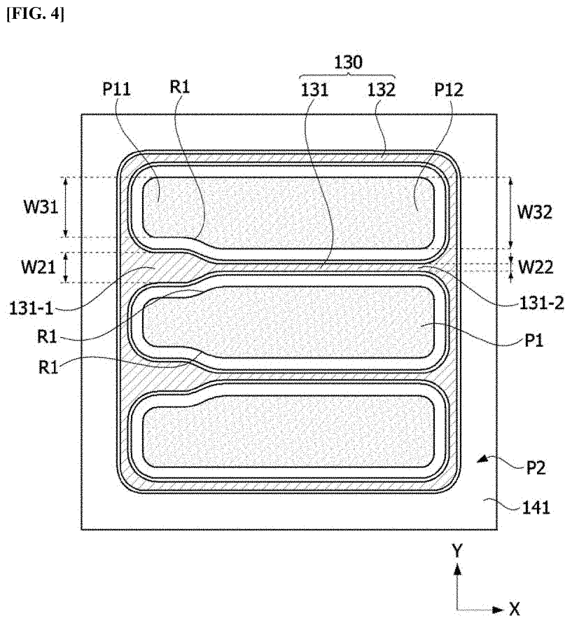

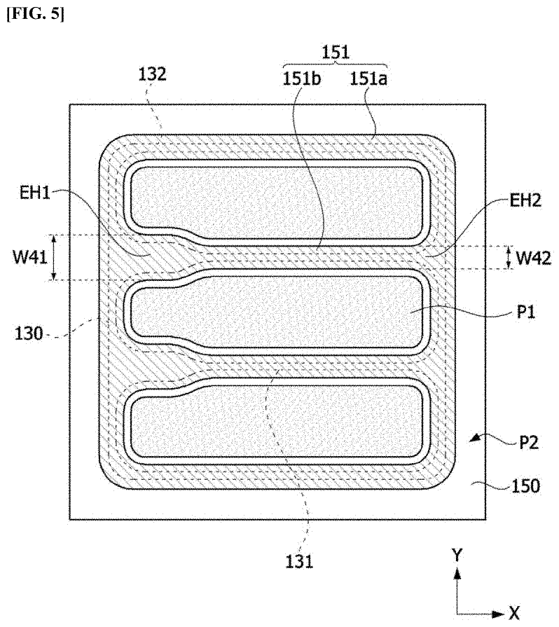

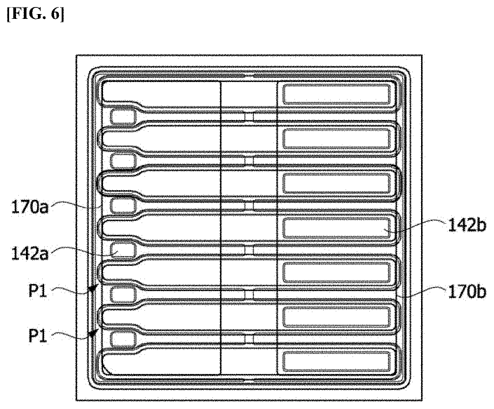

FIG. 3 is a partially enlarged view of ‘A’ in FIG. 2A. FIG. 4 is a plan view showing an intermediate layer surrounding a plurality of light-emitting portions. FIG. 5 is a plan view showing a first contact electrode surrounding a plurality of light-emitting portions.

Referring to FIG. 3, the intermediate layer 130 may be formed on the etched region P2 in which the first conductive type semiconductor layer 121 is exposed through the first through-hole 141a of the first insulating layer 141.

The first contact electrode 151 is disposed on the intermediate layer 130 and extended to an upper portion of the first insulating layer 141. Further, the first contact electrode 151 is inserted in a first spacing region EA1 between the first through-hole 140a and the intermediate layer 130 and is in contact with the first conductive type semiconductor layer 121. With this structure, the reflective area is enlarged, thereby improving light extraction efficiency and dispersion efficiency.

The first cover electrode 152 may be disposed on the first contact electrode 151. The area of the first cover electrode 152 may be smaller than the area of the first contact electrode 151. However, without limitations, the first cover electrode 152 may be formed more largely than the area of the first contact electrode 151 and completely cover the first contact electrode 151.

The second cover electrode 162 may be inserted in a second spacing region EA2 between the second contact electrode 161 and the first insulating layer 141 and be in contact with the second conductive type semiconductor layer 123. With this structure, the reflective area is enlarged, thereby improving light extraction efficiency and dispersion efficiency.

The second contact electrode 161 may include Ni/Au or Ni/Rh. Further, the second cover electrode 162 may include contain Ni/Al or Ti/Al. Therefore, the second cover electrode 162 may have higher ultraviolet reflectivity than the second contact electrode 161.

However, a region of the second cover electrode 162, which overlaps the second contact electrode 161, may substantially decrease reflective efficiency. This is because the second contact electrode 161 may absorb some ultraviolet light due to its relatively low reflectivity. Therefore, in terms of reflecting the ultraviolet light, it may be advantageous to decrease relatively the area of the second contact electrode 161 but increase relatively the area of the second cover electrode 162.

According to an embodiment, the second spacing region EA2 may be formed between the second contact electrode 161 and the first insulating layer 141, and the second contact electrode 161 may be inserted in the second spacing region EA2.

In the region where the second conductive type semiconductor layer 123 is exposed through the second through-hole 141b, the reflectivity of the second spacing region EA2 where the second cover electrode 162 is disposed may be higher than the reflectivity of the region where the second contact electrode 161 is disposed. Further, the reflectivity of a region EA3 where the second cover electrode 162 is extended outwards beyond the second contact electrode 161 may also be higher than the reflectivity of the region where the second contact electrode 161 is disposed. With this structure, the second contact electrode 161 has good ohmic properties and reflects some of the ultraviolet light, and the second cover electrode 162 extended outwards beyond the second contact electrode 161 increases the ultraviolet reflection efficiency. To increase the ultraviolet reflection efficiency, the second cover electrode 162 may be extended up to the lateral surface of the light-emitting portion P1.

The whole region of the second contact electrode 161 overlaps the second cover electrode 162 in the vertical direction, and the area of the second cover electrode 162 may be larger than the area of the first contact electrode 151. In this case, the top surface of the first cover electrode 152 may have substantially the same height as the top surface of the second cover electrode 162.

Referring to FIG. 4, the intermediate layer 130 may include a first intermediate region (or a branch region) 131 disposed between the plurality of light-emitting portions P1, and a second intermediate region (or an edge region) 132 surrounding the edges of the first conductive type semiconductor layer 121 and connected to the opposite ends 131a and 131b of the plurality of first intermediate regions 131. The first intermediate region 131 may be defined as a region that overlaps the plurality of light-emitting portions P1 in a second direction (in the direction of a Y-axis), and the second intermediate region 132 may be defined as a square ring shape surrounding the plurality of light-emitting portions P1.

The plurality of light-emitting portions P1 may include curved portions R1 formed in opposite regions. The curved portions R1 may be formed in a direction where the plurality of light-emitting portions P1 are away from each other. In the light-emitting portion P1, the width W31 of a first end portion P11 may be smaller than the width W32 of a second end portion P12.

In the first intermediate region 131 of the intermediate layer 130, the width W21 of a first end portion 131-1 disposed between the curved portions R1 may be larger than the width W22 of the second end portion 131-2. Therefore, the area of the first end portion 131-1 electrically connected to the electrode pad is enlarged, thereby improving a current spreading effect.

Referring to FIG. 5, the first contact electrode 151 may include a first sub-electrode (or a branch electrode) 151b disposed on the first intermediate region 131, and a second sub-electrode (or an edge electrode) 151a disposed on the second intermediate region 132. In other words, the first contact electrode 151 may have a shape corresponding to the intermediate layer 130. In the first sub-electrode 151b, the width W41 of a first end portion EH1 may be formed more largely than the width W42 of a second end portion EH2. The first sub-electrode 151b may be defined as a region that overlaps the plurality of light-emitting portions P1 in the second direction (or the direction of the Y-axis), and the second sub-electrode 151a may be defined as a square ring shape surrounding the plurality of light-emitting portions P1.

Table 1 shows that the measured areas of the first contact electrode, the intermediate layer, and the first cover electrode are tabulated according to the chip sizes of the light-emitting device, and Table 2 shows that the measured areas of the active layer, the second contact electrode, and the second cover electrode are tabulated according to the chip sizes of the light-emitting device.

TABLE 1

| | Area of | Area of | Area of |
|---|---|---|---|
| Chip | first contact | intermediate | first cover |
| size (mm) | electrode | layer | electrode |
| 10 | 100% | 97% | 80% |
| 15 | 100% | 70% | 69% |
| 20 | 100% | 85% | 85% |
| 30 | 100% | 82% | 70% |
| 40 | 100% | 84% | 62% |
| 48 | 100% | 82% | 70% |

TABLE 2

| | Area of | Area of | Area of |
|---|---|---|---|
| Chip | active | second contact | second cover |
| size (mm) | layer | electrode | electrode |
| 10 | 100% | 65% | 76% |
| 15 | 100% | 78% | 84% |
| 20 | 100% | 79% | 85% |
| 30 | 100% | 79% | 85% |
| 40 | 100% | 75% | 87% |
| 48 | 100% | 80% | 86% |

Referring to Table 1, each area of the intermediate layer 130 and the first cover electrode 152 is smaller than the area of the first contact electrode 151. With this configuration, the area of the first contact electrode 151 is large enough to have the advantage of increasing the reflection efficiency and the current spreading effect. Further, the area of the intermediate layer 130 is larger than the area of the first cover electrode 152. Therefore, the area of the intermediate layer 130 is relatively enlarged to increase the area for contact with the first contact electrode 151, thereby improving the current spreading effect.

Further, referring to Table 2, the area of the second cover electrode 162 is formed more largely than the area of the second contact electrode 161. Therefore, the second cover electrode 162 completely covers the second contact electrode 161 and is disposed even in the second spacing region EA2, thereby improving the reflection efficiency.

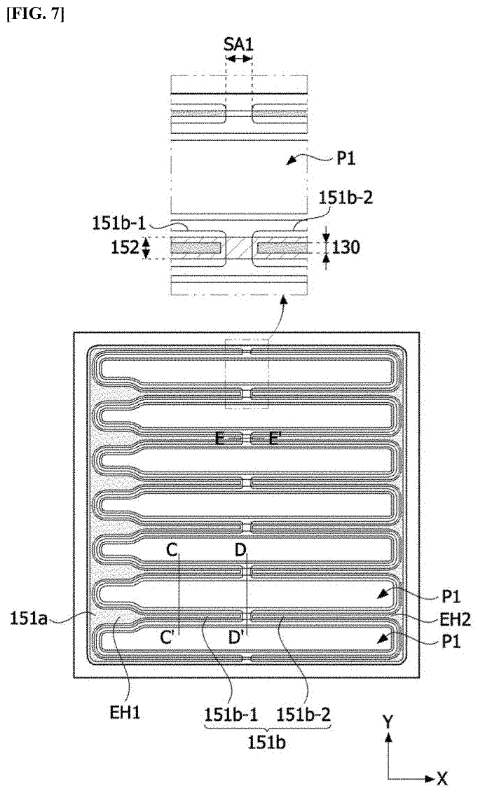

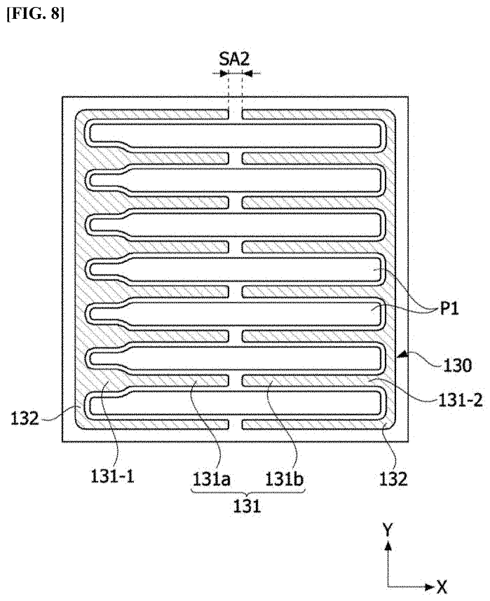

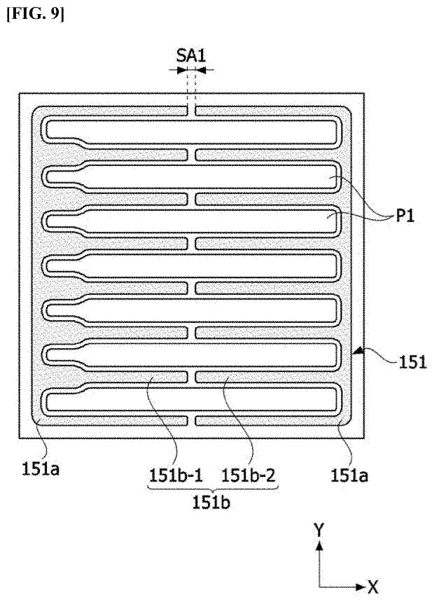

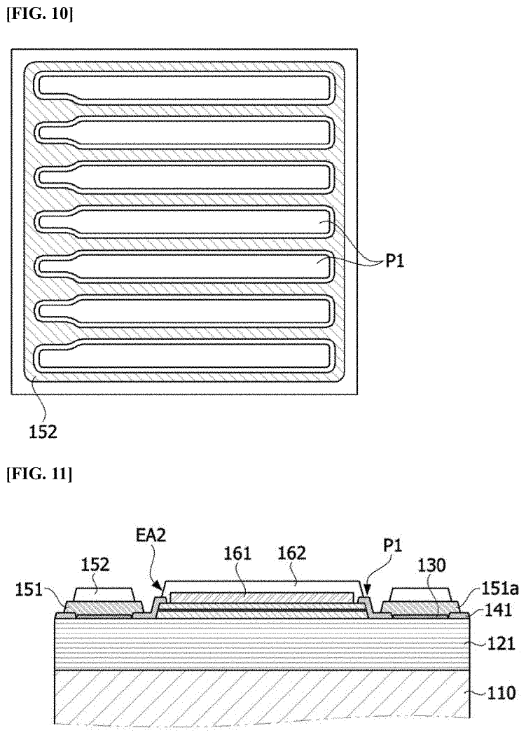

FIG. 6 is a plan view showing a light-emitting device according to another embodiment of the disclosure. FIG. 7 is a plan view showing an intermediate layer, a first contact electrode, and a first cover electrode. FIG. 8 is a plan view showing an intermediate layer with a second splitting region. FIG. 9 is a plan view showing a first contact electrode with a first splitting region. FIG. 10 is a plan view showing a first cover electrode.

Referring to FIG. 6, the light-emitting portion P1 is split into a plurality of pieces to increase the exposed area of the active layer 122, there improving the extraction efficiency of the light emitted through the lateral surface. The embodiment discloses seven light-emitting portions P1, but the number of light-emitting portions P1 may decrease or increase.

Referring to FIGS. 7 and 8, the intermediate layer 130 may include a plurality of first intermediate regions 131 disposed between the plurality of light-emitting portions P1, and a second intermediate region 132 electrically connected to the opposite ends of the plurality of first intermediate regions 131.

The first intermediate region 131 may be a region disposed between the plurality of light-emitting portions P1. The width of the first intermediate region 131 may be varied in a first direction (or the direction of an X-axis). For example, the width of the first end portion 131-1 in the first intermediate region 131 may be larger than the width of the second end portion 131-2.

The second intermediate region 132 is formed along the edge region of the first conductive type semiconductor layer 121 and electrically connected to both end portions 131-1 and 131-2 of the plurality of first intermediate region 131. The second intermediate region 132 may have a square ring shape, and the plurality of light-emitting portions P1 may be placed inside the second intermediate region 132.

The first intermediate region 131 and the second intermediate region 132 may have a plurality of second splitting regions SA2. The first intermediate region 131 may be split into a plurality of sub regions 131a and 131b. Likewise, the second intermediate region 132 may also be split into a plurality of pieces. The plurality of second splitting regions SA2 may be arranged in the second direction (or the direction of the Y-axis) perpendicular to the first direction (or the direction of the X-axis).

Referring to FIG. 9, the first contact electrode 151 may include a plurality of first sub-electrodes 151b disposed between the plurality of light-emitting portions P1, and second sub-electrodes 151a electrically connected to both ends of the plurality of first sub-electrodes 151b.

The first sub-electrode 151b and the second sub-electrode 151a may have a plurality of first splitting regions SAL The first sub-electrode 151b may be split into a plurality of split electrodes 151b-1 and 151b-2. Likewise, the second sub-electrode 151a may also be split into a plurality of pieces. The plurality of first splitting regions SA1 may overlap with each other in the second direction (or the direction of the Y-axis).

In the first contact electrode 151, the first sub-electrode 151b may be disposed on the first intermediate region 131, and the second sub-electrode 151a may be disposed on the second intermediate region 132. Further, the first splitting regions SA1 and the second splitting region SA2 may overlap. In other words, the first contact electrode 151 and the intermediate layer 130 are different in the area but have substantially the same shape.

Referring to FIG. 10, the first cover electrode 152 is disposed on the first contact electrode 151 and may not have a splitting region. Therefore, the first cover electrode 152 may be formed on the first splitting region SA1 of the first contact electrode 151 and electrically connect the split first sub-electrodes 151b.

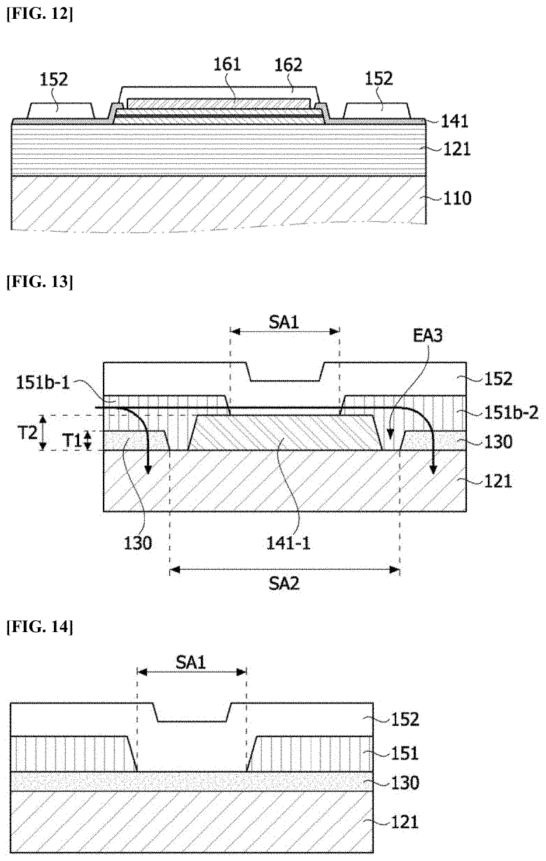

FIG. 11 is a cross-sectional view taken along line C-C′ in FIG. 7. FIG. 12 is a cross-sectional view taken along line D-D′ in FIG. 7. FIG. 13 is a cross-sectional view taken along line E-E′ in FIG. 7.

Referring to FIG. 11, the first contact electrode 151 may be thicker than the second contact electrode 161. To align the height of the first cover electrode 152 with the height of the second cover electrode 162, the first contact electrode 151 may be relatively thickly formed. If the thickness of the first contact electrode 151 is almost equal to the thickness of the second contact electrode 161, the first cover electrode 152 needs to be relatively excessively thick, making fabrication difficult.

Referring to FIG. 12, the first contact electrode 151 may be removed from the first splitting region SAL Therefore, the first contact electrode 151 is not connected to the first splitting region SA1, and therefore the height of the first cover electrode 152 disposed on the first splitting region SA1 may be lower than the height of the second cover electrode 162 disposed on the light-emitting portion P1.

Referring to FIG. 13, the first insulating layer 141 may include an insulating pattern 141-1 disposed in the first splitting region SA1. The intermediate layer 130 may have the second splitting region SA2 corresponding to the first splitting region SAL The spacing distance of the second splitting region SA2 may be larger than that of the first splitting region SA1.

In the second splitting region SA2, the first contact electrode 151 is inserted in the third spacing region EA3, in which the intermediate layer 130 and the insulating pattern 141-1 are spaced apart from each other, and is in contact with the first conductive type semiconductor layer 121. With this structure, stack coverage may be improved.

The thickness T1 of the intermediate layer 130 may be smaller than the thickness T2 of the first insulating layer 141 including the insulating pattern 141-1. The first insulating layer 141 may have a thickness of 10 nm to 300 nm to effectively prevent moisture, contamination, etc. Further, the intermediate layer 130 may have a thickness 10 nm to 150 nm, or a thickness of 10 nm to 100 nm to lower light absorption.

The first cover electrode 152 is continuously formed on the first splitting region SA1 and electrically connects the split electrodes 151b-1 and 151b-2 of the first sub-electrode 151b. With this structure, a spacing region in which current injection is not allowed is formed in the middle when current flows from one side of the first sub-electrode 151b to the other side, thereby increasing a current spreading distance.

In the first splitting region SA1, current is not injected into the first conductive type semiconductor layer 121. Therefore, current to be injected into the position corresponding to the first splitting region SA1 if the first splitting region SA1 is not present is injected into a region where the second split electrode 151b-2 is positioned while passing over the first splitting region SAL Therefore, the current spreading distance is increased.

Referring to FIGS. 7 and 13, if the first splitting region SA1 is absent, most of the current injected into a first end portion EH1 of the first sub-electrode 151b through the third through-hole 142a may be injected into the first end portion EH1 of the first sub-electrode 151b, and relatively small current may be injected into the second end portion EH2 of the first sub-electrode 151b. However, when there is an appropriate number of first splitting regions SA1, a considerable amount of current to be injected into the first end portion EH1 can flow up to the second end portion EH2. Therefore, current can be effectively injected from one end of the first conductive type semiconductor layer 121 to the other end. As a result, the optical power is improved.

The spacing distance of the first splitting region SA1 may range from 5 μm to 100 μm. When the spacing distance of the first splitting region SA1 is shorter than 5 μm, the space is too narrow to substantially increase the current spreading distance. On the other hand, when the spacing distance of the first splitting region SA1 is longer than 100 μm, the space is too wide to spread the current. The number of first splitting regions SA1 may range from 1 to 20, but is not limited thereto.

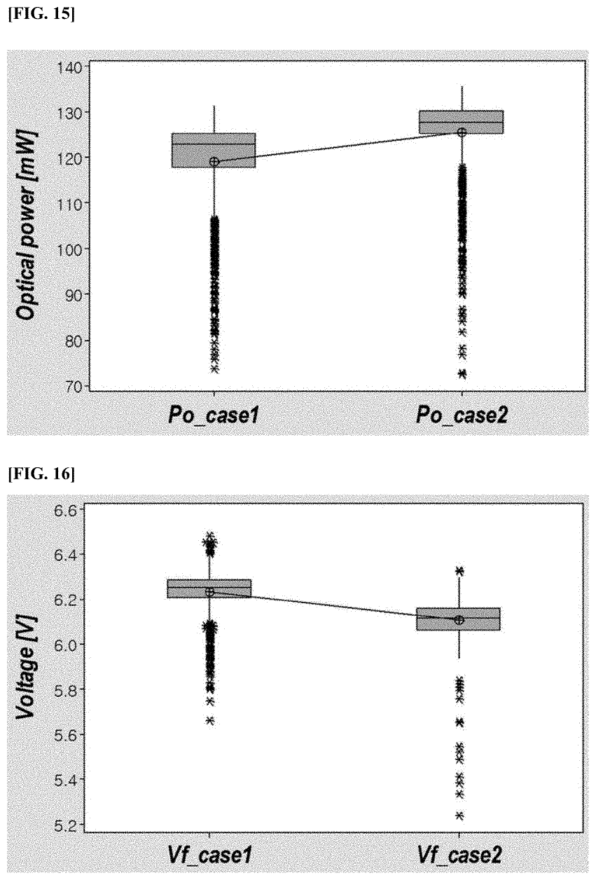

Referring to FIG. 14, the intermediate layer 130 may be continuously formed in the first splitting region SA1 where the first sub-electrode 151b is split. With this configuration, the intermediate layer 130 may have an overall connected shape on the first conductive type semiconductor layer 121, but the first contact electrode 151 is split in the first splitting region SAL In this case, the first cover electrode 152 may be disposed in the first splitting region SA1 and electrically connected to the intermediate layer 130. Further, the intermediate layer 130 may be split in the first splitting region SA1.

FIG. 15 is a graph showing optical power measured in a comparative example where a splitting region is absent from a first contact electrode and an embodiment where a splitting region is present in a first contact electrode. FIG. 16 is a graph showing operating voltage measured in a comparative example where a splitting region is absent from a first contact electrode and an embodiment where a splitting region is present in a first contact electrode.

Referring to FIG. 15, the optical power of the embodiment Po_case2 where the first splitting region SA1 is present in the first contact electrode 151 was more improved than that of the comparative example Po_case1 where the first splitting region is absent in the first contact electrode. Further, referring to FIG. 16, the operating voltage of the embodiment Po_case2 where the first splitting region SA1 is present in the first contact electrode 151 was lower than that of the comparative example Po_case1 where the first splitting region is absent in the first contact electrode. As shown therein, when the first splitting region SA1 is partially formed in the first contact electrode 151, the current spreading distance increases, thereby improving the optical power.

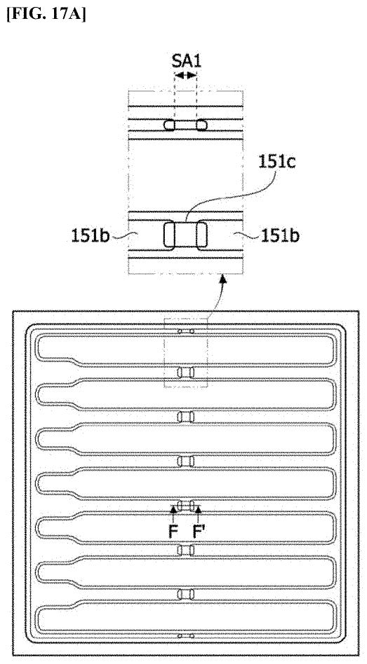

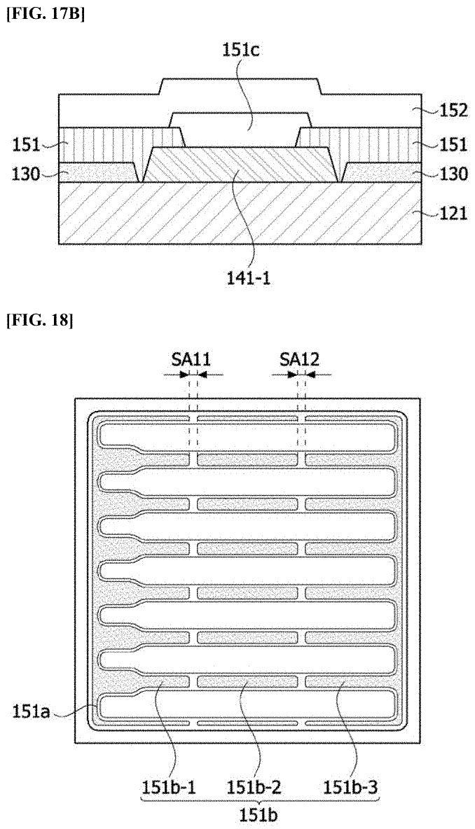

FIG. 17A is a plan view of a light-emitting device according to another embodiment of the disclosure. FIG. 17B is a cross-sectional view, taken along line F-F′ in FIG. 17A.

Referring to FIGS. 17A and 17B, a connection electrode 151c may be disposed in the first splitting region SA1 of the first sub-electrode 151b and connect the split first sub-electrode 151b. The connection electrode 151c may be disposed on the insulating pattern 141-1 and extended to the neighboring first sub-electrode 151b. On the first splitting region SA1, there may be a structure where the insulating pattern 141-1, the connection electrode 151c, and the first cover electrode 152 are stacked.

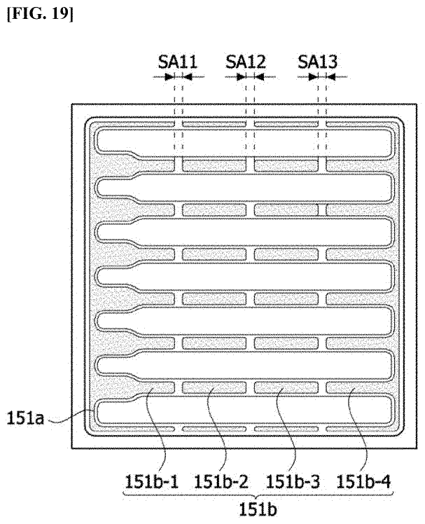

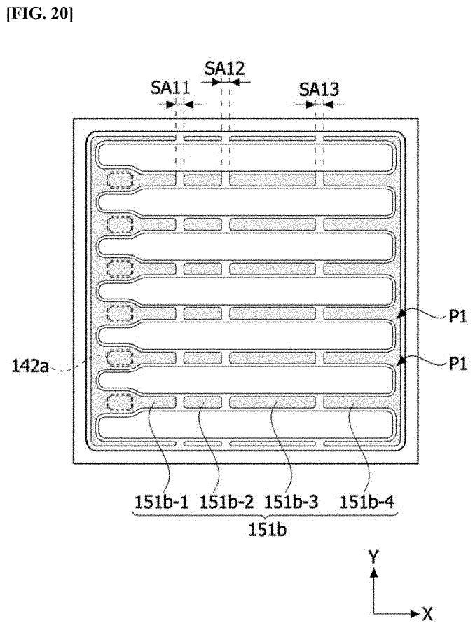

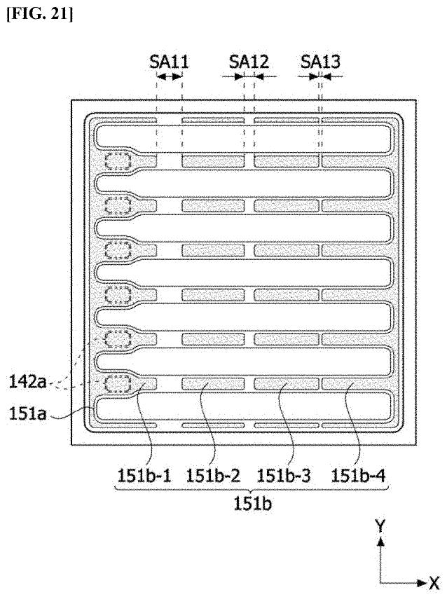

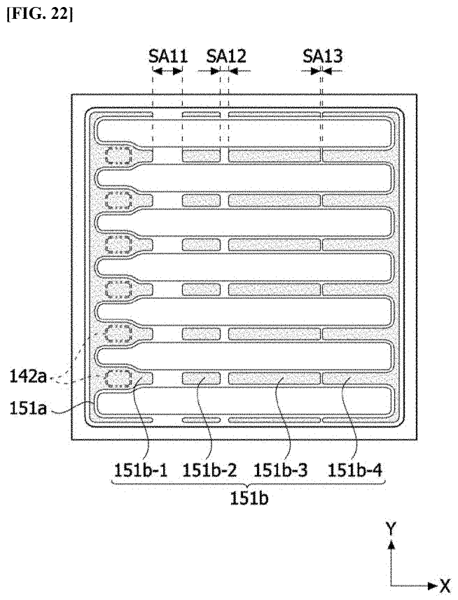

FIG. 18 is a first alternative example to FIG. 9. FIG. 19 is a second alternative example to FIG. 9. FIG. 20 is a third alternative example to FIG. 9. FIG. 21 is a fourth alternative example to FIG. 9. FIG. 22 is a fifth alternative example to FIG. 9.

Referring to FIG. 18, two first splitting regions SA11 and SA12 may be formed in the first sub-electrode 151b. Therefore, the first sub-electrode 151b may include three split electrodes 151b-1, 151b-2, and 151b-3. Among them, the first split electrode 151b-1 and the third split electrode 151b-3 may be connected to the second sub-electrode 151a.

Referring to FIG. 19, three first splitting regions SA11, SA12, and SA13 may be formed in the first sub-electrode 151b. Therefore, the first sub-electrode 151b may include four split electrodes 151b-1, 151b-2, 151b-3, and 151b-4. Among them, the first split electrode 151b-1 and the fourth split electrode 151b-4 may be connected to the second sub-electrode 151a.

Referring to FIG. 20, the insulating layer includes the third through-hole 142a through which a first pad 170a passes, and the plurality of split electrodes 151b-1, 151b-2, 151b-3, and 151b-4 may gradually increase in length as far away from the third through-hole 142a. However, without limitations, the plurality of split electrodes 151b-1, 151b-2, 151b-3, and 151b-4 may gradually decrease in length as far away from the third through-hole 142a.

Referring to FIG. 21, the first splitting regions SA11, SA12, and SA13 may gradually decrease in length as far away from the third through-hole 142a. However, without limitations, the first splitting regions SA11, SA12, and SA13 may gradually increase in length as far away from the third through-hole 142a

Referring to FIG. 22, the split electrodes 151b-1, 151b-2, 151b-3 and 151b-4 may gradually increase in length and the first splitting regions SA11, SA12 and SA13 may gradually decrease in spacing distance as far away from the third through-hole 142a. However, without limitations, the split electrodes 151b-1, 151b-2, 151b-3 and 151b-4 may gradually decrease in length and the first splitting regions SA11, SA12 and SA13 may gradually increase in spacing distance as far away from the third through-hole 142a. Further, the first splitting regions SA1 formed in the plurality of first sub-electrodes 151b may be misaligned with one another in the direction perpendicular to the extending direction (or in the direction of the Y-axis).

Such an ultraviolet light-emitting device may be applied to various light source devices. For example, the light source devices may include a sterilization device, a hardening device, a lighting device, a display device, a vehicle lamp, etc. In other words, the ultraviolet light-emitting device may be applied to various electronic devices in the form of a light-emitting device package disposed in a case (or a body).

The sterilization device may include the ultraviolet light-emitting device according to an embodiment to sterilize a desired region. The sterilization may be applied to a water purifier, an air conditioner, a refrigerator, and the like household appliances, but is not limited thereto. In other words, the sterilization device may be applied to various products (e.g., medical devices) required to undergo sterilization. For example, the water purifier may include a sterilization device according to an embodiment to sterilize circulating water. The sterilization device may be disposed at a nozzle or discharging hole through which water circulates, and emit ultraviolet light. In this case, the sterilization device may have a waterproof structure.

The hardening device may include the ultraviolet light-emitting device according to an embodiment to harden various kinds of liquid. In a broad sense, the liquid may include various materials that become hardened when irradiated with ultraviolet light. For example, the hardening device may harden various kinds of resin. Further, the hardening device may be used in hardening nail polish and the like cosmetic products.

The lighting device may include a substrate, a light source module including the ultraviolet light-emitting device according to the embodiment, a heat sink for dissipating heat from the light source module, and a power supply for processing or converting an electric signal received from the outside to supply the processed signal to the light source module. Further, the lighting device may include a lamp, a headlamp, a street lamp, etc.

The display device may include a bottom cover, a reflection plate, a light-emitting module, a light-guiding plate, an optical sheet, a display panel, an image signal output circuit, and a color filter. The bottom cover, the reflection plate, the light-emitting module, the light-guiding plate, and the optical sheet may make up a backlight unit.

Although the foregoing descriptions have been made focusing on the embodiment, these are merely examples that do not limit the disclosure, and it will be understood for a person having ordinary knowledge in the art to which the disclosure pertains that various modifications and applications not illustrated above can be made without departing from the fundamental characteristics of the embodiment. For example, change can be made in the specific elements according to the embodiment. Further, differences in such modifications and applications fall within the scope of the disclosure defined in the appended claims.

1. An ultraviolet light-emitting device comprising:
a light-emitting structure comprising a plurality of light-emitting portions disposed on a first conductive type semiconductor layer, the plurality of light-emitting portions comprising an active layer and a second conductive type semiconductor layer;
a first contact electrode disposed on the first conductive type semiconductor layer;
a second contact electrode disposed on the second conductive type semiconductor layer;
a first cover electrode disposed on the first contact electrode; and
a second cover electrode disposed on the second contact electrode,
wherein the light-emitting structure comprises an intermediate layer formed in an etched region through which the first conductive type semiconductor layer is exposed, the intermediate layer comprising a lower composition of aluminum than the first conductive type semiconductor layer,
wherein the intermediate layer comprises a first intermediate region disposed between the plurality of light-emitting portions, and a second intermediate region surrounding edges of the first conductive type semiconductor layer and connected to opposite ends of the plurality of first intermediate regions,
wherein the first contact electrode comprises a first sub-electrode disposed on the first intermediate region, and a second sub-electrode disposed on the second intermediate region.

2. The ultraviolet light-emitting device of claim 1, wherein the second contact electrode comprises a material different from the material of the first contact electrode.

3. The ultraviolet light-emitting device of claim 2, wherein the second contact electrode comprises gold (Au) or rhodium (Rh).

4. The ultraviolet light-emitting device of claim 1, further comprising a first insulating layer that is formed on the etched region and comprises a first through-hole through which the intermediate layer is exposed,
wherein a first spacing region is formed between the intermediate layer and the first through-hole.

5. The ultraviolet light-emitting device of claim 4, wherein the first contact electrode covers an upper portion of the first insulating layer, and the first contact electrode is formed in the first spacing region and is in contact with the first conductive type semiconductor layer.

6. The ultraviolet light-emitting device of claim 4, wherein
the first insulating layer comprises a second through-hole through which the second conductive type semiconductor layer is partially exposed,
the second contact electrode is disposed on the second conductive type semiconductor layer exposed through the second through-hole, and
a second spacing region is formed being spaced apart from the second through-hole.

7. The ultraviolet light-emitting device of claim 6, wherein the second cover electrode is extended to an upper portion of the first insulating layer, inserted in the second spacing region, and in contact with the second conductive type semiconductor layer.

8. The ultraviolet light-emitting device of claim 7, wherein the second spacing region in the region where the second conductive type semiconductor layer is exposed through the second through-hole has higher reflectivity than a region disposed in the first cover electrode.

9. The ultraviolet light-emitting device of claim 1, wherein
a total area of the first contact electrode is larger than that of the first cover electrode, and
a total area of the second contact electrode is smaller than that of the second cover electrode.

10. The ultraviolet light-emitting device of claim 9, wherein a total area of the intermediate layer is larger than that of the first cover electrode.

11. The ultraviolet light-emitting device of claim 1, wherein the first contact electrode comprises a plurality of split electrodes spaced apart from each other.

12. The ultraviolet light-emitting device of claim 1, wherein the first cover electrode is disposed on the plurality of split electrodes.

13. The ultraviolet light-emitting device of claim 12, wherein spaces between the plurality of split electrodes are different.

14. The ultraviolet light-emitting device of claim 11, further comprising an insulating pattern disposed in a region where the first contact electrodes are spaced apart from each other.
